(19) United States
(12) Patent Application Publication
(10) Pub. No.: US 2012/0300947 A1
(43) Pub. Date: Nov. 29, 2012

(54) SIGNAL CONVERTER WITH OVERCURRENT PROTECTION MECHANISM

(76) Inventors: Chun-Wei LIN, Yunlin County (TW); Bing-Shiun Hsieh, Yunlin County (TW)

(21) Appl. No.: 13/113,289

(22) Filed: May 23, 2011

(51) Int. Cl. H03G 11/00; H03K 7/08

(52) U.S. Cl. 381/55; 332/109

(57) ABSTRACT

A signal converter with an overcurrent protection mechanism comprises a pulse width modulation (PWM) unit, a timing processing and multi-level conversion unit, an overcurrent detection unit, and a pulse width control unit. The PWM unit converts an analog signal into a pulse signal. The timing processing and multi-level conversion unit receives the pulse signal and converts the pulse signal into a multi-level digital signal. The overcurrent detection unit has a reference voltage terminal outputting a reference voltage. The overcurrent detection unit receives the multi-level digital signal and converts the multi-level digital signal into a detection voltage. The pulse width control unit compares the detection voltage with the reference voltage and outputs a control signal to the PWM unit. Thereby is formed a feedback mechanism to adjust the output voltage and prevent the succeeding circuit from being damaged caused by overcurrent of the pulse signal.

### FIELD OF THE INVENTION

The present invention relates to a signal converter, particularly to a signal converter with an overcurrent protection mechanism.

### BACKGROUND OF THE INVENTION

The current trend is towards fabricating slim, compact and portable multimedia products. In consideration of portable characteristic, the batteries of multimedia products should have longer running time to benefit portability. Besides, high fidelity and high sampling frequency should also be taken into account to effectively promote the audio quality of multimedia products.

In the conventional technologies, the signal converters may be categorized into class A, class B and class AB amplifiers. The class A amplifier features lower audio distortion but has worse energy efficiency. The class B amplifier features higher energy efficiency but has greater audio distortion. The class AB amplifier functions between the class A amplifier and the class B amplifier, and can eliminate the crossover distortion occurring in the class B amplifier. The class AB amplifier has the advantages of lower static current (lower static power consumption) comparing to the class A amplifier and lower distortion comparing to the class B amplifier. However, the class AB amplifier has the disadvantage of higher static power consumption comparing to the class B amplifier and the need of additional heat sink.

Refer to FIG. 1 for the conventional class D audio amplifier. The class D audio amplifier has very high power efficiency comparing to the linear amplifier—100% in theory. Because of high power efficiency, the class D audio amplifier generates less heat, and is free of additional heat sink. Therefore, the class D audio amplifier can be economically manufactured. The class D audio amplifier comprises a modulation circuit 1, an amplifier circuit 2 and a low-pass filter 3. The modulation circuit 1 usually uses a PWM (Pulse Width Modulation) function or a SDM (Sigma Delta Modulation) function. The modulation circuit 1 converts an input audio signal 5 into a two-level voltage signal 6 which is shown in pulse width. The two-level voltage signal 6 is used to control ON/OFF of the amplifier circuit 2 to perform current amplification. Then, the signal is restored through the low-pass filter 3 and outputted by a speaker 4.

The input audio signal 5 is converted by the modulation circuit 1 into the two-level voltage signal 6, and the two-level voltage signal 6 is amplified by the amplifier circuit 2. After the amplification, the signal is still a two-level voltage signal 6. The succeeding low-pass filter 3 filters out the high-frequency harmonic wave to decrease the affection of noise and electromagnetic interference. In the time domain, the low-pass filter 3 functions as an integrator, and gradually accumulates or releases the signal levels or signal energy to restore the modulated signal.

The two-level voltage signal 6 has great instantaneous voltage difference. Thus, the low-pass filter 3 is hard to accumulate signal energy rapidly, and the signals are likely to have phase difference. Therefore, the output voltage has signal distortion 7 and cannot be easily restored to the audio signal with high fidelity and low distortion. Compared with the input audio signal 5 having sine wave, the two-level voltage signal 6 has much signal distortion 7.

A US Publication No. 20110019837 entitled “Multi-Level Output Signal Converter” discloses a multi-level signal converter converting a two-level voltage signal with high-level difference into a multi-level voltage signal with low-level difference, whereby is greatly simplified the design complexity of a conventional low-pass filter, and whereby is obviously decreased the high-frequency harmonic interference, and whereby is reduced the signal distortion caused by the amplifier circuit, and whereby is effectively increased the signal resolution. However, the greater the input signal, the higher the voltage of the output signal after being converted. If the output signal has a voltage higher than the threshold value, not only causes serious distortion but also damages the succeeding circuit.

### SUMMARY OF THE INVENTION

The primary objective of the present invention is to overcome the conventional problems that the output signal has a voltage higher than the threshold value to cause serious distortion and damage the succeeding circuit.

To achieve the above-mentioned objective, the present invention proposes a signal converter with an overcurrent protection mechanism, which comprises a pulse width modulation (PWM) unit, a timing processing and multi-level conversion unit, an overcurrent detection unit, and a pulse width control unit. The PWM unit converts an analog signal into a pulse signal whose width varies with the value of the analog signal. The timing processing and multi-level conversion unit connects with the PWM unit to receive the pulse signal and output a multi-level digital signal via an output terminal. The overcurrent detection unit connects with the timing processing and multi-level conversion unit and has a detection voltage terminal and a reference voltage terminal. The overcurrent detection unit receives the multi-level digital signal and performs conversion to output a detection voltage via the detection voltage terminal, and outputs a reference voltage via the reference voltage terminal. The pulse width control unit connects respectively with the overcurrent detection unit and the PWM unit, and receives the detection voltage and the reference voltage to perform comparison to output a control signal to the PWM unit.

Via the above-mentioned structure, the present invention uses the overcurrent detection unit, the pulse width control unit and the PWM unit to form a feedback mechanism to adjust the output voltage, which prevents the output signal from having a too high voltage to cause serious distortion and avoids the output voltage from exceeding the threshold voltage to damage the succeeding circuit.

### BRIEF DESCRIPTION OF THE DRAWINGS

FIG. 1 is a diagram schematically showing the conventional class D amplifier;

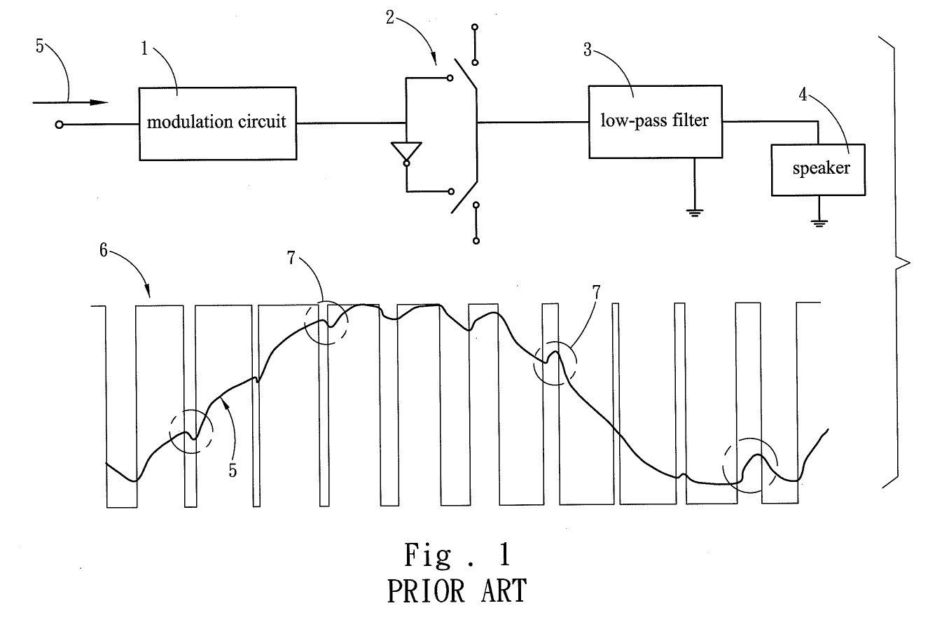

FIG. 2 is a block diagram schematically showing the architecture of a signal converter with an overcurrent protection mechanism according to one embodiment of the present invention;

FIG. 3 is a diagram schematically showing a timing processing and multi-level conversion unit according to one embodiment of the present invention;

FIG. 4 is a circuit diagram schematically showing a multi-level converter according to one embodiment of the present invention;

FIG. 5 is a circuit diagram schematically showing an overcurrent detection unit according to one embodiment of the present invention;

FIG. 6 is a diagram schematically showing the control mechanism of a pulse width control unit according to one embodiment of the present invention;

FIG. 7A is a block diagram schematically showing the architecture of a PWM unit according to one embodiment of the present invention;

FIG. 7B is a diagram schematically showing the pulse width and the conversion waveform according to one embodiment of the present invention;

FIG. 8 is a diagram showing the output voltage according to one embodiment of the present invention;

FIG. 9 is a diagram showing variation of THD according to one embodiment of the present invention; and

FIG. 10 is a diagram showing variation of power efficiency according to one embodiment of the present invention.

### DETAILED DESCRIPTION OF THE PREFERRED EMBODIMENTS

The technical contents of the present invention will be described in detail in cooperation with the drawings below.

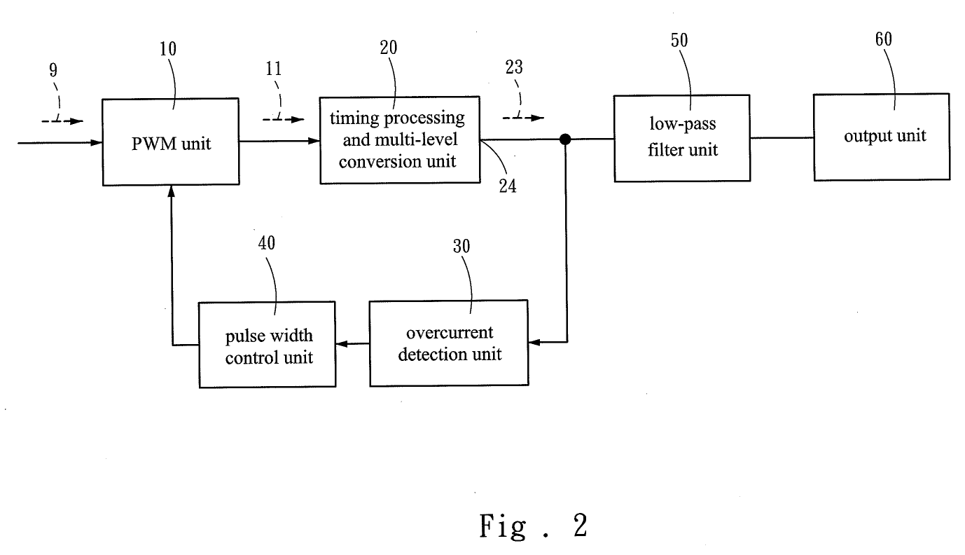

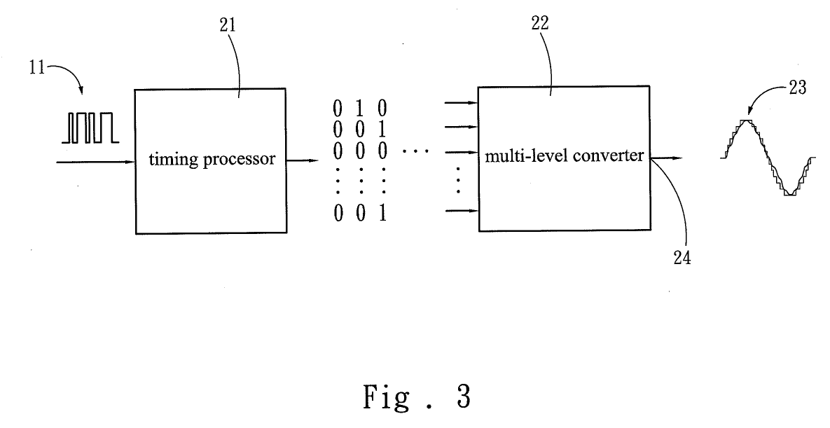

Refer to FIG. 2 and FIG. 3. FIG. 2 is a block diagram schematically showing the architecture of a signal converter with an overcurrent protection mechanism according to one embodiment of the present invention. FIG. 3 is a diagram schematically showing a timing processing and multi-level conversion unit according to one embodiment of the present invention. The present invention proposes a signal converter with an overcurrent protection mechanism, which comprises a pulse width modulation (PWM) unit 10, a timing processing and multi-level conversion unit 20, an overcurrent detection unit 30, and a pulse width control unit 40. The PWM unit 10 converts an analog signal 9 into a pulse signal 11 whose width varies with the value of the analog signal 9. In one embodiment of the present invention, the analog signal 9 is an audio output signal. The timing processing and multi-level conversion unit 20 connects with the PWM unit 10 to receive the pulse signal 11 and output a multi-level digital signal 23 via an output terminal 24. The overcurrent detection unit 30 connects with the timing processing and multi-level conversion unit 20 and has a detection voltage terminal 31 and a reference voltage terminal 32. The overcurrent detection unit 30 receives the multi-level digital signal 23 and performs conversion to output a detection voltage via the detection voltage terminal 31, and outputs a reference voltage via the reference voltage terminal 32. The pulse width control unit 40 connects respectively with the overcurrent detection unit 30 and the PWM unit 10, and receives the detection voltage and the reference voltage to perform comparison to output a control signal to the PWM unit 10. The present invention is mainly used in the conversion and output of audio signals. The present invention may further comprise a low-pass filter unit 50 and an output unit 60. The low-pass filter unit 50 connects with the timing processing and multi-level conversion unit 20. The output unit 60 connects with the timing processing and multi-level conversion unit 20 via the low-pass filter unit 50 to output the multi-level digital signal 23. The output unit 60 may be a loudspeaker, a megaphone, or a headphone, which is able to output audio signals.

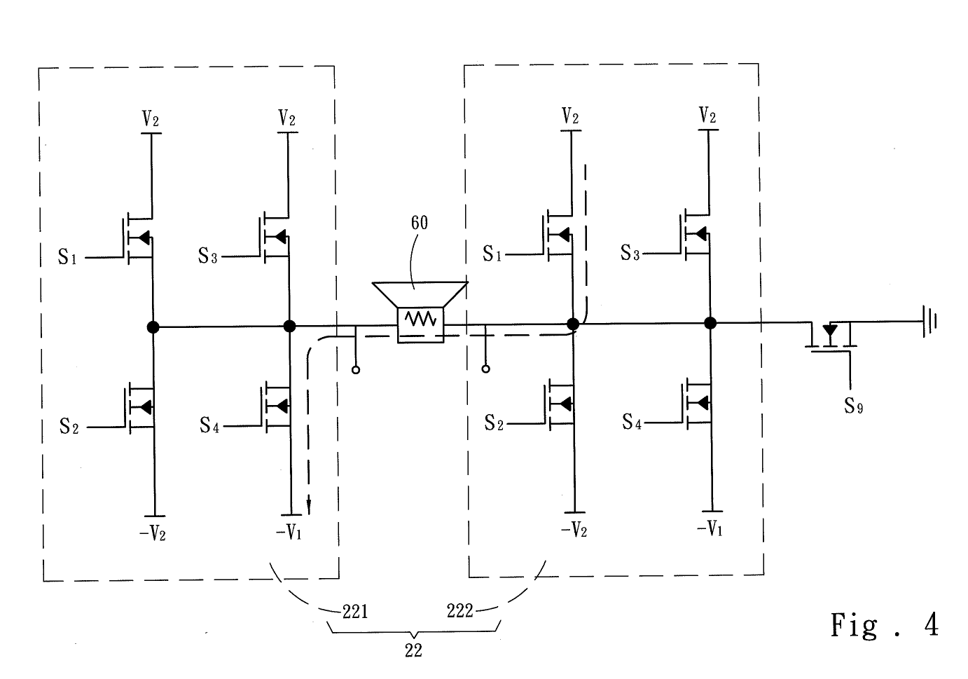

Refer to FIG. 3. The timing processing and multi-level conversion unit 20 has a timing processor 21 and a multi-level converter 22. After receiving the pulse signal 11, the timing processor 21 performs timing processing. The multi-level converter 22 converts the processed pulse signal 11 into the multi-level digital signal 23. FIG. 4 is a circuit diagram schematically showing a multi-level converter according to one embodiment of the present invention. The multi-level converter 22 has two bridge circuits 221 and 222 connecting with each other and connects with the output unit 60 to output audio signals.

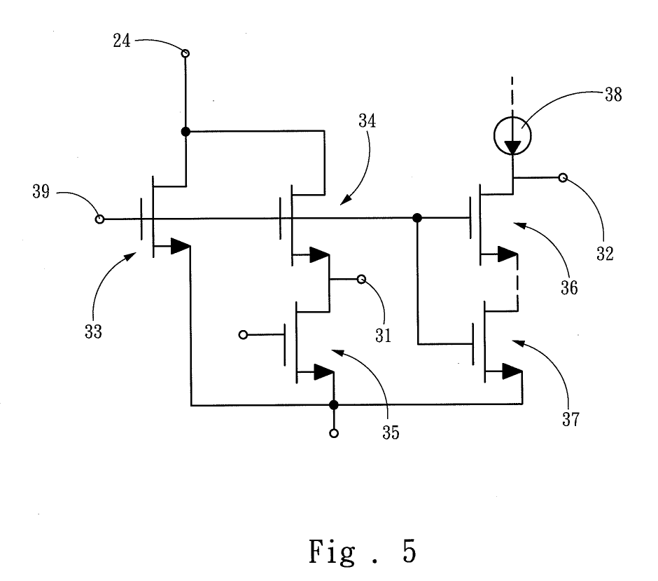

The overcurrent detection unit 30 connects with the multi-level converter 22 to receive the multi-level digital signal 23. Refer to FIG. 5 a circuit diagram schematically showing an overcurrent detection unit according to one embodiment of the present invention. The overcurrent detection unit 30 has five transistors including a first transistor 33, a second transistor 34, a third transistor 35, a fourth transistor 36 and a fifth transistor 37. In the embodiment shown in FIG. 5, the transistors are exemplified by MOS transistors, and the gates, sources and drains thereof are not designated in FIG. 5. The first transistor 33 has a first drain connecting with the output terminal 24, a first source and a first gate. The second transistor 34 has a second drain connecting with the output terminal 24, a second source connecting with the detection voltage terminal 31, and a second gate connecting with the first gate. The third transistor 35 has a third drain connecting with the second source, a third source connecting with the first source, and a third gate. The fourth transistor 36 has a fourth drain connecting with a reference current source 38 and the reference voltage terminal 32, a fourth source, and a fourth gate connecting respectively with the first and second gates. The fifth transistor 37 has a fifth drain connecting with the fourth source, a fifth source connecting with the third source, and a fifth gate connecting with the fourth gate. The first, second, fourth and fifth gates connect with a voltage input terminal 39 which inputs high voltage to conduct the first, second, fourth and fifth transistors. The second transistor 34 connects with the output terminal 24 and outputs the detection voltage via the detection voltage terminal 31 according to the current value of the output terminal 24. The fourth and fifth transistors 36 and 37 receive the signal of the reference current source 38 and output the reference voltage via the reference voltage terminal 32.

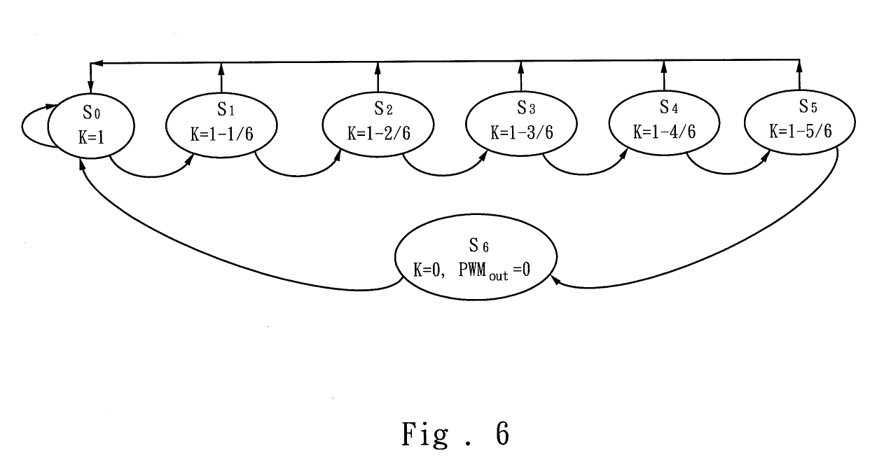

The pulse width control unit 40 performs adjustment according to the reference voltage and the detection voltage. Refer to FIG. 6. The reference voltage has a constant voltage value. When the detection voltage outputted by the detection voltage terminal 31 is higher than the reference voltage, the detection voltage is assumed to exceed the threshold value that the circuit can withstand. Thus, a protection mechanism is started. The protection mechanism is performed by controlling the value of an adjustment factor K. The adjustment factor K controls the pulse width of the signal output by the PWM unit 10, which will be described in detail thereinafter. The adjustment factor K is preset to be 1. When the detection voltage is higher than the reference voltage, the pulse width control unit 40 will reduce the adjustment factor K by a specific value firstly. In FIG. 6, the specific value is ⅙, and the adjustment factor K can be reduced by 6 levels. If the detection voltage is still higher than the reference voltage, the adjustment factor K is further reduced by ⅙. The above-mentioned step will be repeated until the detection voltage is lower than the reference voltage. If the detection voltage has been lower than the reference voltage, the adjustment factor K is increased by ⅙ to meet the dynamic variation of signals lest the overall signal intensity attenuates. If the adjustment factor K has been reduced to 0, the circuit is determined to short circuit or malfunction.

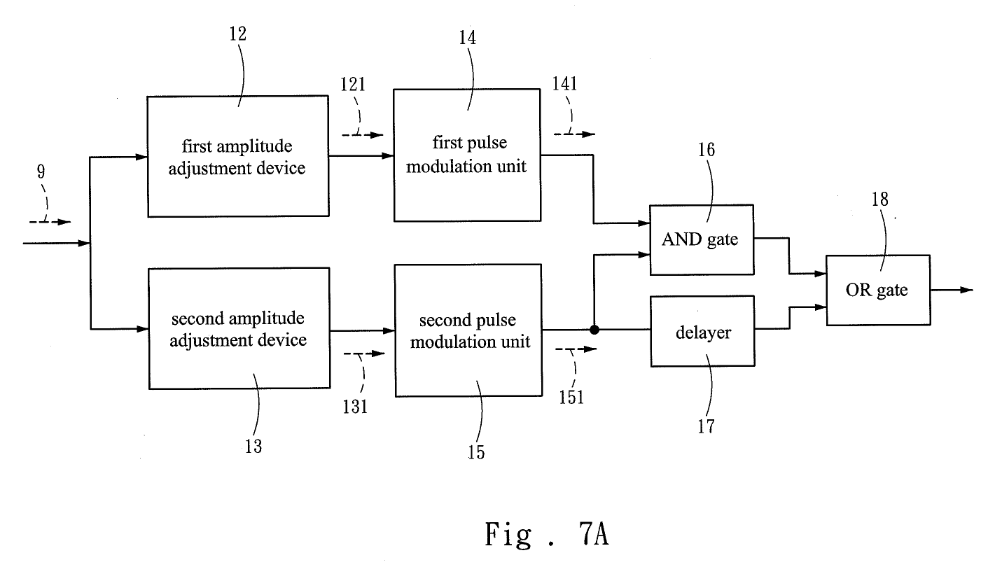

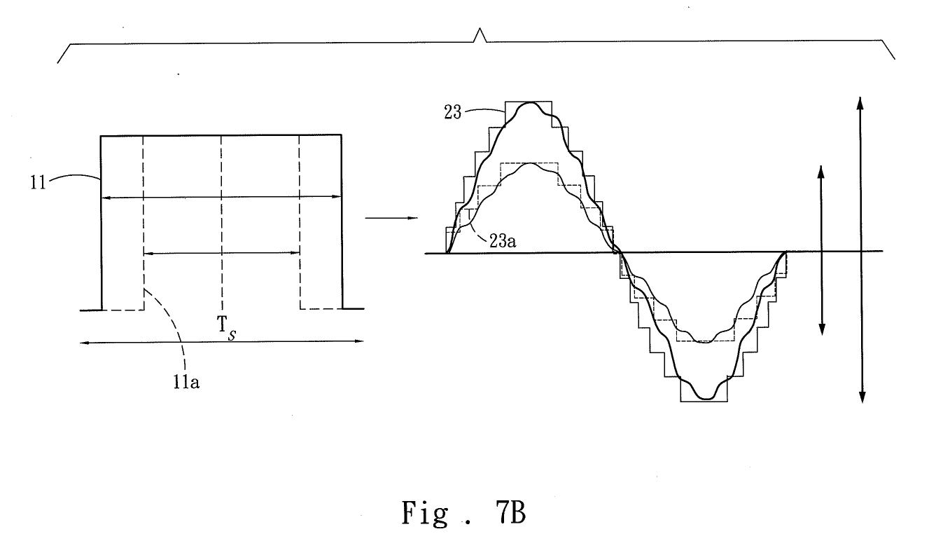

Refer to FIG. 7A a block diagram schematically showing the architecture of a PWM unit according to one embodiment of the present invention. The PWM unit 10 includes a first amplitude adjustment device 12 receiving the analog signal 9, a second amplitude adjustment device 13 receiving the analog signal 9, a first pulse modulation unit 14, a second pulse modulation unit 15, an AND gate 16, a delayer 17 and an OR gate 18. The first amplitude adjustment device 12 receives the analog signal 9 and converts the analog signal 9 into a first amplitude signal 121. In one embodiment, the first amplitude adjustment device 12 is a signal amplifier, and the amplification ratio thereof is the adjustment factor K. The analog signal 9 multiplied by the adjustment factor K equals to the first amplitude signal 121. If the adjustment factor K of the first amplitude adjustment device 12 is 1, it means that the analog signal 9 is neither amplified nor reduced but is forwarded directly to the next device. The first pulse modulation unit 14 connects with the first amplitude adjustment device 12 and converts the first amplitude signal 121 into a first PWM signal 141.

The second amplitude adjustment device 13 connects with the pulse width control unit 40. The pulse width control unit 40 controls the adjustment factor K of the second amplitude adjustment device 13. The second amplitude adjustment device 13 uses the control signal to control the adjustment factor K to adjust the amplitude of the analog signal 9, and outputs a second amplitude signal 131. The adjustment factor K is smaller than or equal to 1. The adjustment method has been described above and no more repeats. The second pulse modulation unit 15 connects with the second amplitude adjustment device 13 and converts the second amplitude signal 131 into a second PWM signal 151. The AND gate 16 connects respectively with the first pulse modulation unit 14 and the second pulse modulation unit 15, and receives the first PWM signal 141 and the second PWM signal 151 to perform a logical operation. Refer to FIG. 7B. The operation of the AND gate 16 controls the width of the positive half cycle of the pulse signal 11 and thus controls the amplitude of the positive half cycle of the multi-level digital signal 23. The delayer 17 and the OR gate 18 connect with each other to control the width of the negative half cycle of the pulse signal 11 and thus control the amplitude of the negative half cycle of the multi-level digital signal 23. Via the adjustment of the second PWM signal 151, the original pulse signal 11 is converted into an adjusted pulse signal 11a. Thus, the original multi-level digital signal 23 is converted into an adjusted multi-level digital signal 23a according to the adjusted pulse signal 11a. Thereby, the voltage neither exceeds the threshold value nor causes serious distortion/damages the succeeding circuit.

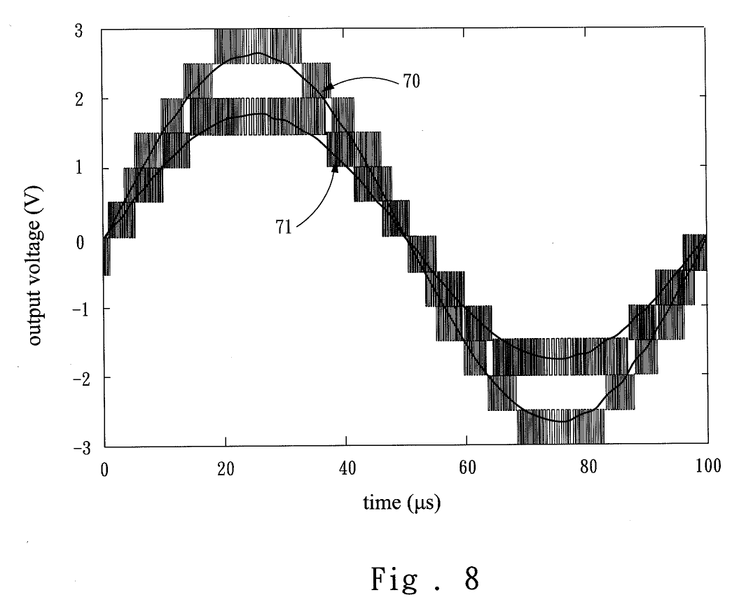

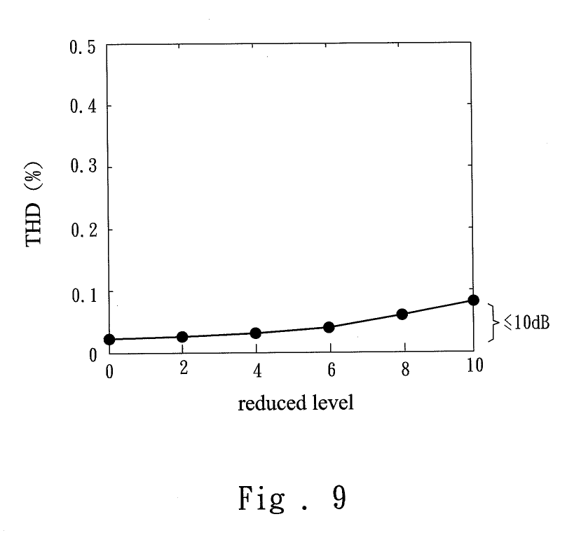

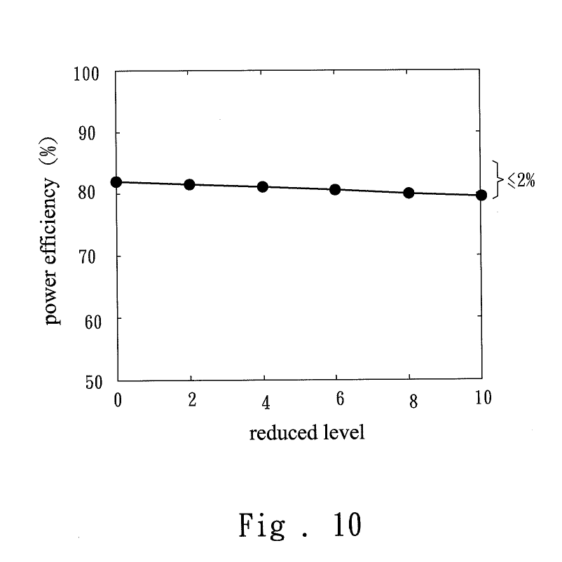

Refer to FIG. 8 a diagram showing the output voltage received by the output unit 60 according to one embodiment of the present invention. In FIG. 8, there are a first output voltage curve 70 not detected by the overcurrent detection unit 30 and a second output voltage curve 71 detected by the overcurrent detection unit 30. The second output voltage curve 71 detected by the overcurrent detection unit 30 can be reduced by 4 levels, and the peak voltage thereof is effectively decreased lest it exceeds the threshold value. Refer to FIG. 9. In FIG. 9, THDs (Total Harmonic Distortion) of the signals detected by the overcurrent detection unit 30 are all lower than 0.1, and the differences of THDs in different reduced levels are lower than 10 dB. Refer to FIG. 10. In FIG. 10, the power efficiency is about 80% for all reduced levels, and the differences of the power efficiency in different reduced levels are within 2%.

Refer to Table. 1. THD of the present invention is lower than the two conventional technologies, and SNR (Signal to Noise Ratio) of the present invention is higher than the two conventional technologies. The power consumption of the present invention is greater than the two conventional technologies by 30 mW. However, the power efficiency of the present invention is only 2% lower than the two conventional technologies. Therefore, the overall performance of the present invention is higher than the two conventional technologies.

TABLE.1
comparisons between the present invention and two
conventional technologies

| | THD | SNR | Power | Efficiency |
|---|---|---|---|---|
| Technology | (%) | (dB) | Consumption | (%) |
| The Present | 0.022 | 85 | 220 mW | 80 |
| Invention | | | | |
| Class-D | 1.68 | 55 | 190 mW | 82 |
| Amplifier | | | | |
| Class-D | 0.176 | 58 | 190 mW | 82 |
| Amplifier with | | | | |
| Filter | | | | |

In conclusion, the present invention uses the overcurrent detection unit 30, the pulse width control unit 40 and the PWM unit 10 to form a feedback mechanism, which adjusts the output voltage and prevents the too high pulse signal 11 from causing serious distortion and the output voltage thereof from exceeding the threshold value to damage the succeeding circuit. Further, the present invention much outperforms the conventional technologies in THD and SNR with the power consumption and the power efficiency close to that of the conventional technologies. Therefore, the present invention possesses utility, novelty and non-obviousness and meets the condition for a patent. Thus, the Inventors file the application. It will be appreciated if the patent is approved fast.

The embodiments described above are only to exemplify the present invention but not to limit the scope of the present invention. Any equivalent modification or variation according to the spirit of the present invention is to be also included within the scope of the present invention.

What is claimed is:

1. A signal converter with an overcurrent protection mechanism, comprising:
a pulse width modulation (PWM) unit converting an analog signal into a pulse signal whose width varies with a value of the analog signal;
a timing processing and multi-level conversion unit connecting with the PWM unit to receive the pulse signal and output a multi-level digital signal via an output terminal thereof;
an overcurrent detection unit connecting with the timing processing and multi-level conversion unit, having a detection voltage terminal and a reference voltage terminal, the overcurrent detection unit receiving the multi-level digital signal and performing conversion to output a detection voltage via the detection voltage terminal, and outputting a reference voltage via the reference voltage terminal; and
a pulse width control unit connecting respectively with the overcurrent detection unit and the PWM unit, receiving the detection voltage and the reference voltage to perform comparison to output a control signal to the PWM unit.

2. The signal converter with an overcurrent protection mechanism according to claim 1, wherein the PWM unit further comprises
a first amplitude adjustment device receiving the analog signal and converting the analog signal into a first amplitude signal;
a second amplitude adjustment device receiving the analog signal and connecting with the pulse width control unit to receive the control signal, the second amplitude adjustment device using the control signal to control an adjustment factor to adjust amplitude of the analog signal and output a second amplitude signal, wherein the second amplitude signal equals to the analog signal multiplied by the adjustment factor, and the adjustment factor is smaller than or equal to 1;
a first pulse modulation unit connecting with the first amplitude adjustment device;
a second pulse modulation unit connecting with the second amplitude adjustment device;
an AND gate connecting respectively with the first pulse modulation unit and the second pulse modulation unit;
a delayer connecting with the second pulse modulation unit; and
an OR gate connecting respectively with the AND gate and the delayer.

3. The signal converter with an overcurrent protection mechanism according to claim 2, wherein the first amplitude adjustment device has the adjustment factor equal to 1 and directly outputs the analog signal, and wherein the first amplitude adjustment device and the second amplitude adjustment device are respectively a signal amplifier.

4. The signal converter with an overcurrent protection mechanism according to claim 1, wherein the overcurrent detection unit further comprises
a first transistor including a first drain connecting with the output terminal of the timing processing and multi-level conversion unit, a first source and a first gate;
a second transistor including a second drain connecting with the output terminal of the timing processing and multi-level conversion unit, a second source connecting with the detection voltage terminal, and a second gate connecting with the first gate of the first transistor;
a third transistor including a third drain connecting with the second source, a third source connecting with the first source, and a third gate;
a fourth transistor including a fourth drain connecting respectively with a reference current source and the reference voltage terminal, a fourth source, and a fourth gate connecting with the first gate and the second gate; and
a fifth transistor including a fifth drain connecting with the fourth source, a fifth source connecting with the third source, and a fifth gate connecting with the fourth gate.

5. The signal converter with an overcurrent protection mechanism according to claim 1, wherein the timing processing and multi-level conversion unit includes a timing processor and a multi-level converter.

6. The signal converter with an overcurrent protection mechanism according to claim 5, wherein the multi-level converter includes two bridge circuits connecting with each other.

7. The signal converter with an overcurrent protection mechanism according to claim 1 further comprising an output unit connecting with the timing processing and multi-level conversion unit to output the multi-level digital signal.

8. The signal converter with an overcurrent protection mechanism according to claim 7, wherein the output unit is selected from the group consisting of a loudspeaker, a megaphone, and a headphone.
